(19) United States
(12) Patent Application Publication
(10) Pub. No.: US 2025/0364339 A1
(43) Pub. Date: Nov. 27, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Pin-Jing SU, Taichung City (TW); Wen-Yu TENG, Taichung City (TW); Liang-Yi HUNG, Taichung City (TW); Chia-Cheng CHEN, Taichung City (TW); Yu-Po WANG, Taichung City (TW)

(73) Assignee: SILICONWARE PRECISION INDUSTRIES CO., LTD., Taichung City (TW)

(21) Appl. No.: 18/930,525

(22) Filed: Oct. 29, 2024

(30) Foreign Application Priority Data
May 27, 2024 (TW) 113119530

(51) Int. Cl. H01L 23/31; H01L 21/56; H01L 23/00; H01L 23/367; H01L 23/498

(52) U.S. Cl. CPC H01L 23/3107; H01L 21/566; H01L 23/367; H01L 23/49811; H01L 23/49833; H01L 24/32; H01L 2224/32145

(57) ABSTRACT

An electronic package including a carrier structure, an electronic component bonded to the carrier structure, a heat conduction component bonded to the electronic component, a substrate, and an encapsulating material. A first surface of the substrate is bonded to an area of the carrier structure surrounding the electronic component. An enclosure is formed around the opening, and the encapsulating material at least encapsulates surroundings of the electronic component and the heat conduction component. The present disclosure can prevent the encapsulant overflowing to the top of the heat conduction component and reducing an area of the heat conduction component contacting air, or overflowing to a top surface of the substrate and covering contacts on the top surface of the substrate. Thereby, failures of the electronic package caused by poor heat dissipation or electrical contact can be avoided to improve reliability of the electronic package.

### BACKGROUND

### 1. Technical Field

The present disclosure relates to a semiconductor packaging process, and more particularly, to an electronic package and the manufacturing method thereof.

### 2. Description of Related Art

With the evolution of semiconductor packaging technology, different packaging types have been developed for semiconductor devices. In order to improve the electrical functions of semiconductor devices while saving packaging space, the industry has developed package on package (POP) structures formed by stacking multiple packages. This package stacking structure can achieve system integration by stacking electronic components with different functions, such as memory, central processing unit, graphics processor, imaging application processor, etc., to provide the characteristics of a heterogeneous integrated System in Package (SiP), therefore is suitable for all kinds of thin, light and small electronic products.

FIG. 1A and FIG. 1B are schematic views of a conventional electronic package during the molding process, in which the mold is omitted and not shown. As shown in FIG. 1A and FIG. 1B, the electronic package 1 comprises a chip 10, a first substrate 11, a second substrate 12, a plurality of solder balls 13, and an encapsulant 14. The first substrate 11 has a circuit layer 111, the second substrate 12 has a circuit layer 121, and the second substrate 12 is bonded to and electrically connected to the first substrate 11 through the solder balls 13. The chip 10 is disposed on the first substrate 11 in a flip-chip manner. The encapsulant 14 covers the solder balls 13 and the chip 10. In addition, in order to provide a heat dissipation for the chip 10, an opening 122 is configured in central of the second substrate 12, a heat dissipation block 15 is disposed on the chip 10, and the upper surface of the heat dissipation block 15 is exposed from the opening 122, such that the heat generated by chip 10 can be conducted to external environment through the heat dissipation block 15.

During the process of filling a colloid material to form the encapsulant 14, the upper surfaces of the heat dissipation block 15 and the substrate 12 in the structure of the abovementioned electronic package 1 have to be covered with a release film 16, to prevent the uncured encapsulant 14 from overflowing from the opening 122. However, during the molding process, due to the height difference between the heat dissipation block 15 and the second substrate 12, the release film 16 can only form close contact with the one with a higher top surface, causing the uncured encapsulant 14 to overflow. If, as shown in FIG. 1A, the top surface of the second substrate 12 is higher than the top surface of the heat dissipation block 15, the release film 16 cannot closely contact the heat dissipation block 15, the uncured encapsulant 14 will overflow to the top surface of the heat dissipation block 15, and the contact area between the top surface of the heat dissipation block 15 and the outside air is reduced, resulting in a poor effect of heat dissipation. On the other hand, as shown in FIG. 1B, if the top surface of the heat dissipation block 15 is higher than the top surface of the second substrate 12, the uncured encapsulant 14 will overflow to the top surface of the second substrate 12, and the electrical contacts 123 on the top surface of the second substrate 12 is covered by the encapsulant, resulting in poor electrical contact or poor electrical connection problem subsequently.

Therefore, how to overcome the above-mentioned problems of conventional techniques has become an urgent issue to be solved.

### SUMMARY

In view of the aforementioned shortcomings of the prior art, the present disclosure provides an electronic package, comprising: a carrier structure; an electronic component bonded to the carrier structure; a heat conduction component bonded to the electronic component; a substrate having a first surface, a second surface opposite to the first surface, and an opening connecting the first surface and the second surface and exposing the heat conduction component, wherein the first surface of the substrate is bonded to an area of the carrier structure surrounding the electronic component, the second surface of the substrate is lower than the top surface of the heat conduction component, and an enclosure is formed on an area of the second surface surrounding the opening; and an encapsulating material encapsulating at least surroundings of the electronic component and the heat conduction component, wherein a top surface of the encapsulating material is lower than the top surface of the heat conduction component and a top surface of the enclosure.

The present disclosure further provides a manufacturing method of an electronic package, comprising: providing an electronic module comprising a carrier structure, an electronic component, a heat conduction component and a substrate, wherein the electronic component is bonded to the carrier structure, the heat conduction component is bonded to the electronic component, the substrate has a first surface, a second surface opposite to the first surface, and an opening connecting the first surface and the second surface and exposing the heat conduction component, the first surface of the substrate is bonded to an area of the carrier structure surrounding the electronic component, the second surface of the substrate is lower than a top surface of the heat conduction component, and an enclosure is formed on an area of the second surface surrounding the opening; disposing the electronic module in a mold set and performing molding, to form an encapsulating material encapsulating at least surroundings of the electronic component and the heat conduction component, wherein a top surface of the encapsulating material is lower than the top surface of the heat conduction component and a top surface of the enclosure; and removing the mold set.

In the aforementioned electronic package and the manufacturing method thereof, the mold set includes a sealing component in close contact with the top surface of the heat conduction component, a top surface of the substrate and the top surface of the enclosure.

In the aforementioned electronic package and the manufacturing method thereof, the sealing component is a release film.

In the aforementioned electronic package and the manufacturing method thereof, the heat conduction component is a dummy die.

In the aforementioned electronic package and the manufacturing method thereof, the heat conduction component is bonded to the electronic component through a bonding layer.

In the aforementioned electronic package and the manufacturing method thereof, the substrate is bonded to and electrically connected to the carrier structure through a plurality of conductive components.

In the aforementioned electronic package and the manufacturing method thereof, the substrate comprises a solder mask material and at least one conductive trace and a thickened conductive trace disposed beneath the solder mask material, and the enclosure is composed of the thickened conductive trace and the solder mask material.

In the aforementioned electronic package and the manufacturing method thereof, the enclosure is a continuous enclosure.

In the aforementioned electronic package and the manufacturing method thereof, the enclosure is a discontinuous enclosure.

It can be seen from above, in the electronic package and the manufacturing method thereof in the present disclosure, a tight seal would be certainly formed between the die attach film covering the heat conduction component and the substrate and the top surface of the heat conduction component during molding process by the design of the top surface of the heat conduction component higher than the upper surface of the substrate. Therefore, the encapsulant used to form the encapsulating material overflowing to the top surface of the heat conduction component, and the area of the top surface of the heat conduction component contacting air being reduced can be avoided. In addition, the encapsulant overflowing to the top surface of the substrate and covering the electrical contacts located on the top surface of the substrate can be prevented by forming the enclosure on the substrate surrounding the opening. Therefore, it can be avoidable that the electronic package fails due to poor heat dissipation or poor electrical contact, thereby the reliability of the electronic package can be improved.

### BRIEF DESCRIPTION OF THE DRAWINGS

FIG. 1A and FIG. 1B are schematic views of a conventional electronic package during the molding process.

FIG. 2A to FIG. 2C are schematic cross-sectional views according to an embodiment of the manufacturing method of the electronic package in the present disclosure.

FIG. 2B-1, FIG. 2B-2 and FIG. 2B-3 are schematic top views in different aspects of the enclosure of the electronic package in the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

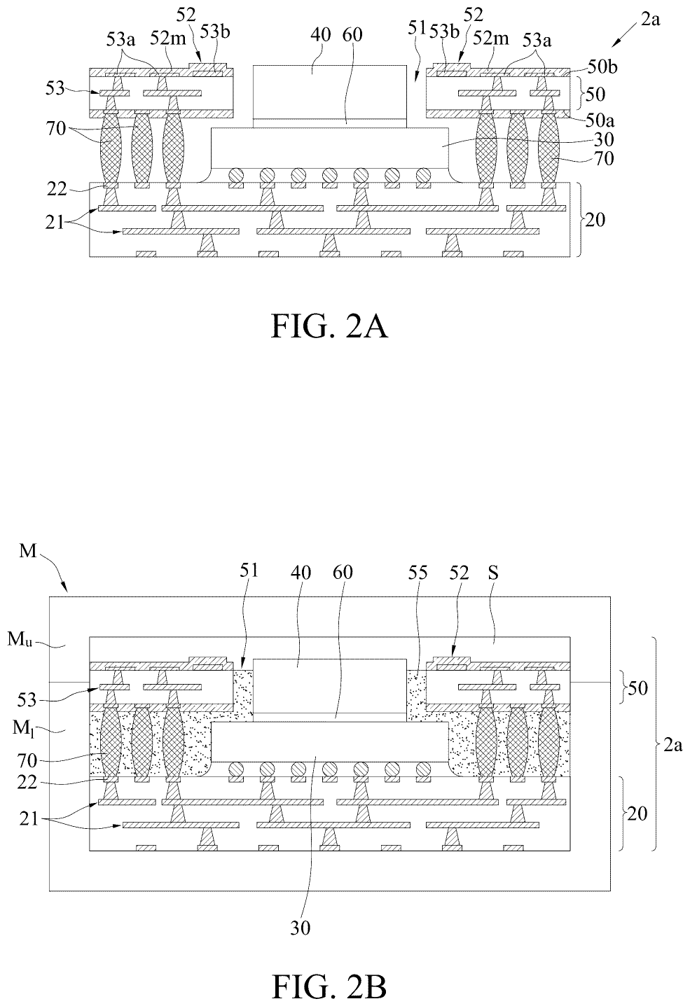

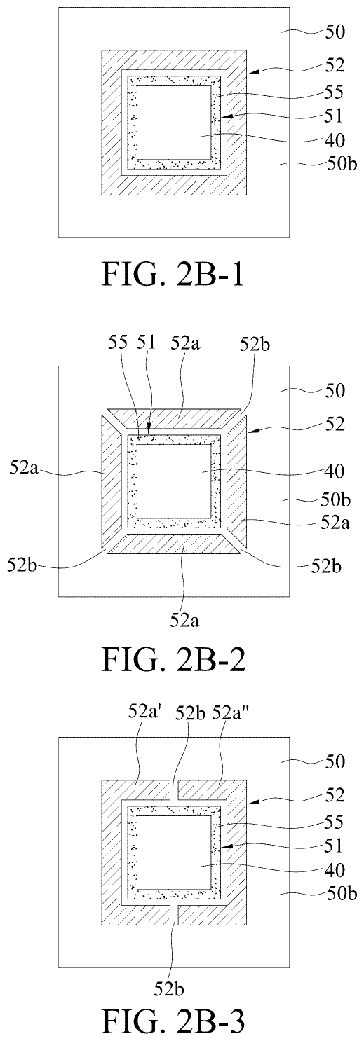

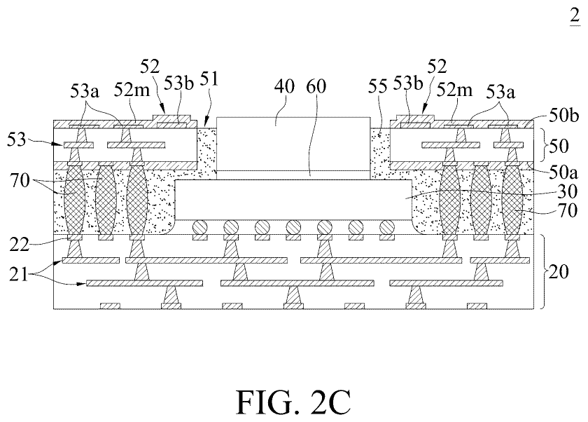

FIG. 2A to FIG. 2C are schematic views according to an embodiment of the manufacturing method of the electronic package in the present disclosure.

As shown in FIG. 2A, in this embodiment, a first step of the manufacturing method is providing an electronic module 2a. The electronic module 2a comprises: a carrier structure 20 formed with at least one first circuit layer 21, an electronic component 30, a heat conduction component 40 and a substrate 50.

The electronic component 30 is bonded to a top surface of the carrier structure 20, and is electrically connected to the first circuit layer 21. The electronic component 30 may be a passive component, such as a resistor, a capacitor or an inductor, or may be an active component. An active semiconductor chip is used as an example in this embodiment but not limited thereto.

The heat conduction component 40 is bonded to a top surface of the electronic component 30 such that heat produced by the electronic component 30 can be conducted to the heat conduction component 40 to assist the electronic component 30 with heat dissipation. In this embodiment, the heat conduction component 40 is a dummy die made of a semiconductor material, but is not limited to this. All the materials and components beneficial to the electronic component 30 for heat dissipation are applicable.

Preferably, the heat conduction component 40 is bonded to the electronic component 30 through a bonding layer 60. The bonding layer 60 can be for example a Die Attach Film (DAF) or any other suitable film or adhesive. There is no limitation for the bonding layer 60 in the present disclosure.

The substrate 50 has a first surface 50a and a second surface 50b opposite to the first surface 50a, and the substrate 50 comprises a solder mask material 52m disposed on its surface and a plurality of second circuit layers 53. The second circuit layer 53 located on a top side of the substrate 50 comprises at least one conductive trace 53a and a thickened conductive trace 53b thicker than the conductive trace 53a, and the at least one conductive trace 53a and the thickened conductive trace 53b are disposed beneath the solder mask material 52m. The first surface 50a of the substrate 50 is a lower surface, and the second surface 50b is an upper surface. The first surface 50a of the substrate 50 is bonded to an area of the carrier structure 20 surrounding the electronic component 30 through a plurality of conductive components 70, and the second circuit layer 53 is electrically connected to part of the electrical connection pads 22 and the first circuit layer 21 in the carrier structure 20 through the conductive components 70. The conductive components 70 may be, for instance, conductive pillars, conductive bumps, etc., and several solder balls are used as an example in this embodiment.

The substrate 50 further has an opening 51 connecting the first surface 50a and the second surface 50b, such that a top surface of the heat conduction component 40 can be exposed from the opening 51. The second surface 50b of the substrate 50 is lower than the top surface of the heat conduction component 40, i.e., the top surface of the heat conduction component 40 is higher than the upper surface of the substrate 50. An enclosure 52 is formed on an area of the second surface 50b of the substrate 50 that corresponds to surroundings of the opening 51. The enclosure 52 is together composed of the thickened conductive trace 53b and the solder mask material 52m covering the thickened conductive trace 53b.

As shown in FIG. 2B, next, disposing the electronic module 2a in a mold set M. The mold set M is for example composed of an upper mold Mᵤ and a lower mold Mₗ which are in a sealed combination such that the electronic module 2a is tightly contacted in an interior of the mold set M. Preferably, the mold set M further includes an additional sealing component S tightly contacting with top surfaces of the heat conduction component 40, the substrate 50 and the enclosure 52 all at the same time. In this embodiment, the sealing component S is a release film, but may also be a film or a thin sheet of other suitable materials, there is no limitation for this in this embodiment.

Then, a material such as an encapsulant is filled to a space among the carrier structure 20, the electronic component 30, the heat conduction component 40, the substrate 50 and the sealing component S within the mold set M to perform the molding process, thereby an encapsulating material 55 is formed on surroundings of the electronic component 30 and the heat conduction component 40. A top surface of the encapsulating material 55 is lower than the top surface of the heat conduction component 40 (the top surface of the heat conduction component 40 may be higher than a top surface of the solder mask material 52m but not higher than the top surface of the enclosure 52). In the meantime, during the process of filling the encapsulant, due to the limitation on the enclosure 52, the encapsulant will not overflow to the second surface 50b outside the enclosure 52 even if the encapsulant is filled such that its top surface is slightly higher than the second surface 50b of the substrate 50, that us, the top surface of the encapsulating material 55 formed is also lower than the top surface of the enclosure 52. Therefore, if an electric contact (not shown) is disposed on the second surface 50b of the substrate 50, the electric contact is not covered by the encapsulant or the encapsulating material 55, and poor electrical contact or electrical connection is not caused subsequently.

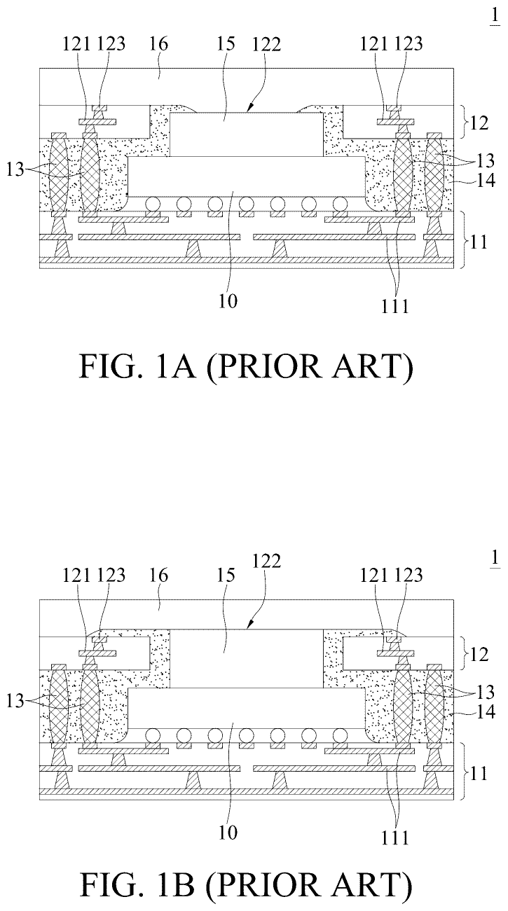

As shown in FIG. 2B-1, the enclosure 52 may be shaped as a continuous enclosure continuously surrounding the surroundings of the opening 51, which can be a closed ring shape. Alternatively, as shown in FIG. 2B-2, the enclosure 52 may also be a discontinuous enclosure composed of four segments 52a respectively formed on each sides on the surroundings of the opening 51, which can be a discontinuous ring shape. A gap 52b is formed between every two adjacent segments 52a. Or, as shown in FIG. 2B-3, the enclosure 52 is in another discontinuous ring shape which is formed by a C-shaped segment 52a′ and an inversed C-shaped segment 52a″, and the gap 52b is also formed between the segments 52a′, 52a″. Since the encapsulant has a quite viscosity, the encapsulant can be limited effectively so as not to overflow during the filling process even if the enclosure 52 is not in the continuous ring shape as long as the filling amount and the width of the gap 52b are properly controlled. Therefore, as long as the encapsulant can be effectively limited to not overflow, there is no unnecessary limitation for the shape of the enclosure 52 in this embodiment.

As shown in FIG. 2C, the whole mold set M including the upper mold Mᵤ, the lower mold Mₗ and the sealing component S is removed after the encapsulating material 55 has been formed. The electronic package 2 shown in this embodiment can be obtained.

This embodiment also provides the electronic package 2 including the carrier structure 20; the electronic component 30 bonded to the top surface of the carrier structure 20; the heat conduction component 40 bonded to the top surface of the electronic component 30; the substrate 50 having the first surface 50a, the second surface 50b opposite to the first surface 50a, and the opening51 connecting the first surface 50a and the second surface 50b and exposing the heat conduction component 40; and an encapsulating material 55 at least encapsulating the surroundings of the electronic component 30 and the heat conduction component 40. The first surface 50a of the substrate 50 is bonded to an area of the carrier structure 20 surrounding the electronic component 30, the second surface 50b of the substrate 50 is lower than the top surface of the heat conduction component 40, and an enclosure 52 is formed on an area of the second surface 50b around the opening 51. The top surface of the encapsulating material 55 is lower than the top surfaces of the heat conduction component 40 and the enclosure 52. The top surface of the heat conduction component 40 may be higher than the top surface of a solder mask material 52m but not higher than the top surface of the enclosure 52.

In some embodiments, the heat conduction component 40 is a dummy die.

In some embodiments, the heat conduction component 40 is bonded to the electronic component 30 through the bonding layer 60.

In some embodiments, the substrate 50 is bonded to and electrically connected to the carrier structure 20 through the plurality of conductive components 70.

In some embodiments, the substrate 50 comprises the solder mask material 52m and at least one conductive trace 53a and a thickened conductive trace 53b disposed beneath the solder mask material 52m, and the enclosure 52 is composed of the thickened conductive trace 53b and the solder mask material 52m.

In some embodiments, the enclosure 52 may surround around the opening 51 continuously or separately.

In summary, in the electronic package and the manufacturing method thereof shown in this embodiment, the sealing component or die attach film covering the heat conduction component and the substrate will certainly form a tight seal with the top surface of the heat conduction component during molding process by the design of the top surface of the heat conduction component higher than the upper surface of the substrate disposed on the carrier structure. Therefore, the encapsulant used to form the encapsulating material overflowing to the top surface of the heat conduction component and the area of the top surface of the heat conduction component contacting air being reduced can be avoided. In addition, poor electrical contact caused by the encapsulant overflowing to the top surface of the substrate and covering the electrical contacts located on the top surface of the substrate can be prevented by forming the enclosure around the opening of the substrate. Therefore, failures of the electronic package due to poor heat dissipation or poor electrical contact can be avoided, thereby the reliability of the electronic package can be improved.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrier structure;
an electronic component bonded to the carrier structure;
a heat conduction component bonded to the electronic component;
a substrate having a first surface, a second surface opposite to the first surface, and an opening connecting the first surface and the second surface and exposing the heat conduction component, wherein the first surface of the substrate is bonded to an area of the carrier structure surrounding the electronic component, the second surface of the substrate is lower than a top surface of the heat conduction component, and an enclosure is formed on an area of the second surface surrounding the opening; and
an encapsulating material encapsulating at least surroundings of the electronic component and the heat conduction component, wherein a top surface of the encapsulating material is lower than the top surface of the heat conduction component and a top surface of the enclosure.

2. The electronic package of claim 1, wherein the heat conduction component is a dummy die.

3. The electronic package of claim 1, wherein the heat conduction component is bonded to the electronic component through a bonding layer.

4. The electronic package of claim 1, wherein the substrate is bonded to and electrically connected to the carrier structure through a plurality of conductive components.

5. The electronic package of claim 1, wherein the substrate comprises a solder mask material and at least one conductive trace and a thickened conductive trace disposed beneath the solder mask material, and the enclosure is composed of the thickened conductive trace and the solder mask material.

6. The electronic package of claim 1, wherein the enclosure is a continuous enclosure.

7. The electronic package of claim 1, wherein the enclosure is a discontinuous enclosure.

8. A manufacturing method of an electronic package, comprising:
providing an electronic module comprising a carrier structure, an electronic component, a heat conduction component and a substrate, wherein the electronic component is bonded to the carrier structure, the heat conduction component is bonded to the electronic component, the substrate has a first surface, a second surface opposite to the first surface and an opening connecting the first surface and the second surface and exposing the heat conduction component, and the first surface of the substrate is bonded to an area of the carrier structure surrounding the electronic component, the second surface of the substrate is lower than a top surface of the heat conduction component, and an enclosure is formed on an area of the second surface surrounding the opening;
disposing the electronic module in a mold set and performing molding, to form an encapsulating material encapsulating at least surroundings of the electronic component and the heat conduction component, wherein a top surface of the encapsulating material is lower than the top surface of the heat conduction component and a top surface of the enclosure; and
removing the mold set.

9. The manufacturing method of the electronic package of claim 8, wherein the mold set includes a sealing component in close contact with the top surface of the heat conduction component, a top surface of the substrate and the top surface of the enclosure.

10. The manufacturing method of the electronic package of claim 9, wherein the sealing component is a release film.

11. The manufacturing method of the electronic package of claim 8, wherein the heat conduction component is a dummy die.

12. The manufacturing method of the electronic package of claim 8, wherein the heat conduction component is bonded to the electronic component through a bonding layer.

13. The manufacturing method of the electronic package of claim 8, wherein the substrate is bonded to and electrically connected to the carrier structure through a plurality of conductive components.

14. The manufacturing method of the electronic package of claim 8, wherein the substrate comprises a solder mask material, and at least one conductive trace and a thickened conductive trace disposed beneath the solder mask material, and the enclosure is composed of the thickened conductive trace and the solder mask material.

15. The manufacturing method of the electronic package of claim 8, wherein the enclosure is a continuous enclosure.

16. The manufacturing method of the electronic package of claim 8, wherein the enclosure is a discontinuous enclosure.
